(19) United States
(12) Patent Application Publication
(10) Pub. No.: US 2013/0122687 A1
(43) Pub. Date: May 16, 2013

(54) LASER SCRIBING SYSTEMS, APPARATUS, AND METHODS

(71) Applicant: Applied Materials, Inc., Santa Clara, CA (US)

(72) Inventor: James Matthew Holden, San Jose, CA (US)

(73) Assignee: APPLIED MATERIALS, INC., Santa Clara, CA (US)

(21) Appl. No.: 13/677,847

(22) Filed: Nov. 15, 2012

Related U.S. Application Data
(60) Provisional application No. 61/560,747, filed on Nov. 16, 2011.

(51) Int. Cl. H01L 21/78

(52) U.S. Cl. CPC H01L 21/78
USPC 438/462; 219/385; 219/201

(57) ABSTRACT

Scribing apparatus are disclosed. In one aspect, a dual-stage scribing apparatus has a first stage adapted to receive a first substrate, a second stage adapted to receive a second substrate, and one or more lasers adapted to emit a laser beam towards the first stage and the second stage and adapted to scribe the substrates. Scribing can be undertaken on the first stage while an orientation process may take place on the other. In another aspect, as dual-laser scribing apparatus is disclosed. Electronic device processing systems and methods including scribing apparatus are described, as are numerous other aspects.

### RELATED APPLICATIONS

The present application claims priority from U.S. Provisional Patent Application Ser. No. 61/560,747, filed Nov. 16, 2011, entitled “SCRIBING SYSTEMS, APPARATUS, AND METHODS” (Attorney Docket No. TBD-100/L/FEG/SYNX) which is hereby incorporated herein by reference in its entirety for all purposes.

### FIELD

The present invention relates to electronic device manufacturing, and more specifically to laser scribing systems, apparatus, and methods adapted to process electronic devices.

### BACKGROUND

In semiconductor wafer processing, integrated circuits are formed on a wafer (also referred to as a “substrate”) made of silicon or other semiconductor material. In general, layers of various materials which are either semiconducting, conducting or insulating are utilized to form the integrated circuits on the wafer. These materials are doped, deposited and etched using various well-known processes to form integrated circuits on the wafer in defined patterns.

Following the formation of the plurality of integrated circuit on the wafer, the wafer may undergo a process to form individual “dice” that may be packaged or used in an unpackaged form within larger circuits. One technique that is used as part of the wafer dicing process is scribing. In one method, the scribing may involve moving a scribe across the wafer surface. These scribing generally extends along the spaces between the individual integrated circuits. These spaces are commonly referred to as “streets.” Although. not commonplace, diamond-tipped scribing may be used for relatively thin wafers (e.g., about 0.25 mm or less). For thicker wafers, sawing may be used as a method for dicing. However, chipping and cracking may be a problem with either scribing or sawing.

Plasma dicing has also been used, but may have limitations as well. For example, one limitation on implementation of plasma dicing may be cost. A standard lithography operation for patterning resist may render implementation cost prohibitive. Another limitation possibly hampering implementation of plasma dicing is that plasma processing of commonly encountered metals (e.g., copper) in dicing along streets can create production issues that may prevent its use.

In another method of dicing, a mask is applied to a top surface of the wafer, the mask composed of a layer covering and protecting the integrated circuits. The mask is then patterned with a pulsed laser scribing process to provide a patterned mask with gaps exposing regions of the wafer between the integrated circuits, i.e., along the streets. The laser scribing may also remove a first layer to expose silicon. The wafer is then etched in an etching process through the gaps in the patterned mask. This etching process singiflates the integrated circuits into dice. However, relatively low throughput and relatively high cost has been a problem associated with existing laser scribing systems.

Accordingly, improved systems, apparatus, and methods for efficient and precise scribing of substrates are desired.

### SUMMARY

In a first aspect, a scribing apparatus is provided. The scribing apparatus includes a first stage adapted to receive a first substrate, a second stage adapted to receive a second substrate, and one or more lasers adapted to emit a laser beam towards the first stage and the second stage and adapted to scribe the substrates.

In a second aspect, an electronic device processing system is provided. The electronic device processing system includes a factory interface, an etching tool coupled to the factory interface, and a dual-stage scribing apparatus coupled to the factory interface.

In another aspect, method of processing a substrate within an electronic device processing system is provided. The method includes providing a dual-stage scribing apparatus having a first stage adapted to receive a first substrate, a second stage adapted to receive a second substrate, and one or more lasers adapted to scribe the first substrate and the second substrate, positioning the first stage at a first location to carry out an orientation process on the first substrate, and positioning the second stage at a second location to carry out laser scribing of the second substrate as the first substrate is undergoing the orientation process.

In another aspect, method of processing a singulated substrate is provided. The method includes providing a singulated substrate having a die attached film, loading the singulated substrate on a stage of a scribing apparatus, and cutting the die attached film with a scribing beam of the scribing apparatus.

In another aspect, a scribing apparatus is provided. The scribing apparatus includes a stage adapted to receive a substrate, a beam delivery head adapted to produce a scribing beam, a first laser adapted to emit a laser beam towards the beam delivery head, and a second laser adapted to emit a laser beam towards the beam delivery head wherein the first beam and second beam are combined within the beam delivery head and produce the scribing beam.

Numerous other features are provided in accordance with these and other aspects of the invention. Other features and aspects of the present invention will become more fully apparent from the following detailed description, the appended claims, and the accompanying drawings.

### BRIEF DESCRIPTION OF THE DRAWINGS

FIG. 1 is a schematic top view of an electronic device processing system including a dual-stage scribing apparatus and etching module coupled to factory interface according to embodiments.

FIG. 2A is a partially cross-sectioned front view of a dual-stage scribing apparatus according to embodiments.

FIG. 2B is a partially cross-sectioned side view of a dual-stage scribing apparatus with the first stage located at a first location according to embodiments.

FIG. 2C is a partially cross-sectioned side view of a dual-stage scribing apparatus with the first stage located at a second location according to embodiments.

FIG. 2D is a partially cross-sectioned side view of a beam delivery head according to embodiments.

FIG. 3 is a schematic top view of an alternative electronic device processing system including a dual-stage scribing apparatus and an etching module coupled to factory interface according to embodiments.

FIG. 4 is a flowchart of a method of processing a substrate within an electronic device processing system according to embodiments.

FIG. 5 is a flowchart of a method of processing a substrate to cut a die attached film according to embodiments.

FIG. 6 is a top view of a singulated substrate adhered to a membrane including a die attached film (DAF) and held in a frame according to embodiments.

### DETAILED DESCRIPTION

Electronic device manufacturing may require very rapid scribing of substrates. In order to improve the throughput and efficiency of scribing process, an electronic device processing system is providing with a dual-stage scribing apparatus. The dual-stage scribing apparatus may be directly coupled to a factory interface. A suitable robot may be used to pass the substrates from the dual-stage scribing apparatus to a process tool, such as an etching module. This same robot apparatus may be used to remove and place substrates to and from substrate carriers docked at the load ports or from other storage vessels coupled to the factory interface. The etching module may include one or more etching process chambers adapted to carry out etching of the substrates along the streets previously scribed by the dual-stage scribing apparatus.

In another aspect, the dual-stage scribing apparatus includes first and second stages that may be arranged in a side-by-side orientation, each adapted to secure a single substrate thereat. A single beam delivery head may be utilized to sequentially scribe each of the substrates. This provides nearly zero wasted laser time as will become apparent from the following. In particular, while a first substrate is being aligned on one stage (e.g., on the first stage), the other substrate (e.g., the second substrate on the second stage) may be undergoing laser scribing. Thus, the laser can be scribing substrates substantially all the time, whereas previous laser scribing systems had to idle the laser while orientation and alignment processes took place, thus resulting in substantial laser idle time.

In another aspect the scribing apparatus may carry out the scribing with two or more lasers including relatively lower relative power requirements. The lower power requirements are achieved by utilizing two superimposed lasers that are combined in close proximity to form a scribing beam. In some embodiments, power requirements of less than about 35 W, less than about 30 W, less than about 25 W, or even less than 15 W per laser can be achieved.

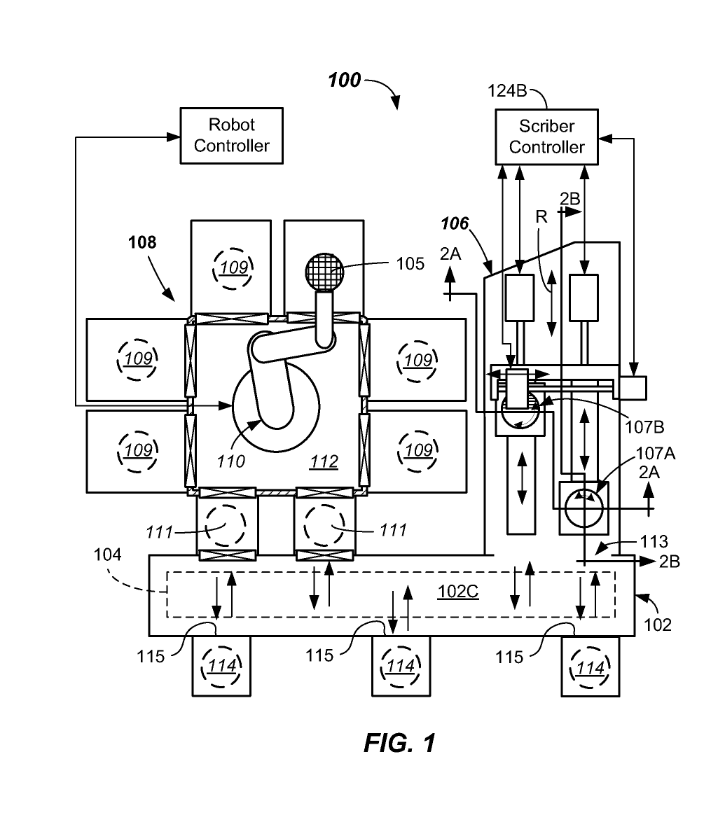

Further details of example embodiments of various aspects and embodiments of the invention are described with reference to FIGS. 1-6 herein.

Referring now to FIG. 1, an example embodiment of an electronic device processing system 100 according to one or more embodiments of the present invention is disclosed. The electronic device processing system 100 is useful and may be configured and adapted to process substrates used to manufacture electronic devices. Substrates may be wafers (e.g., silicon or AlGaAs wafers), glass panels, or the like. The substrates may have many integrated circuits formed in a pattern therein. In some embodiments, the electronic device processing system 100 includes a factory interface 102 having an interface chamber 102C, that may be operated at atmospheric or nearly atmospheric pressure. A slight positive pressure may be provided in some embodiments. Coupled to the factory interface 102 and serviceable by one or more robots 104 (shown dotted) is a dual-stage scribing apparatus 106. The dual-stage scribing apparatus comprises at least two stages.

The dual-stage scribing apparatus 106 may include a first stage 107A and a second stage 107B. Stages 107A, 107B may be rotary stages capable of rotating substrates from a first rotational orientation to one or more second rotational orientations in a Theta rotational direction (as designated by arrows on stages 107A, 107B). Stages 107A, 107B may also be translational stages capable of translating substrates from a first location to a second location within the dual-stage scribing apparatus 106 in an R direction. The stages 107A, 107B may include a linear drive mechanism that moves (e.g., translates) each of the stages 107A, 107B in a translational (e.g., in the R direction). Rotational motors may be coupled to the stages 107A, 107B to carry out rotation thereof.

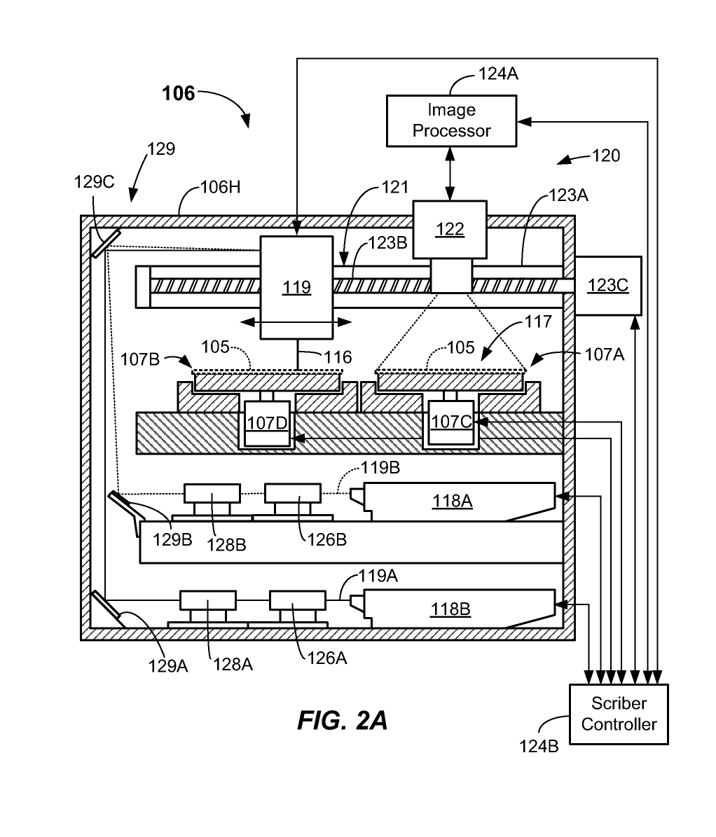

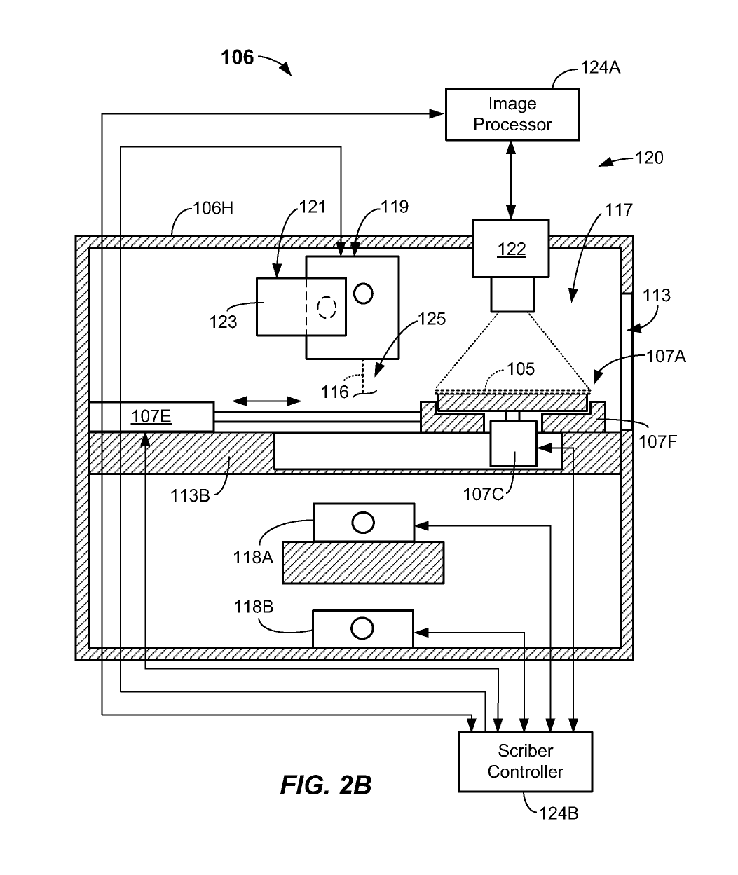

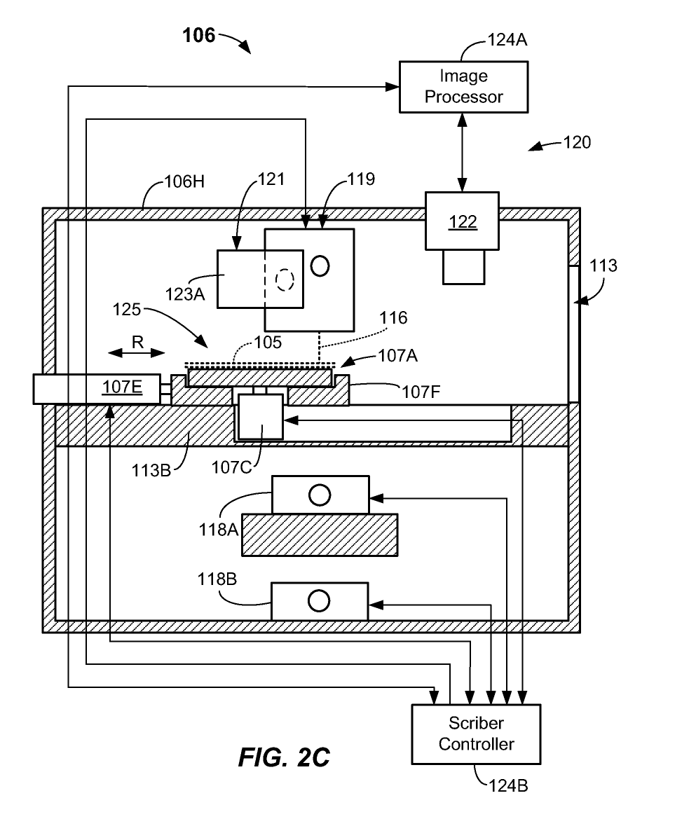

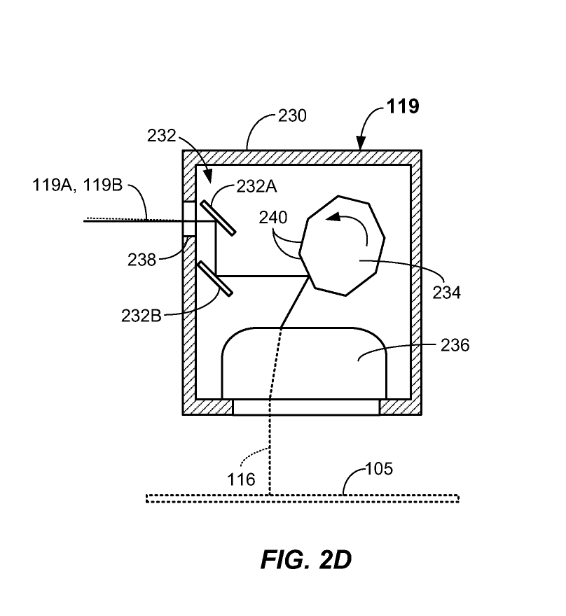

Stages 107A, 107B may be arranged in a side-by-side orientation as shown, and may be positioned as close together as possible. Thus, it should be apparent that stages 107A, 107B may be operational to both rotate and translate the substrates 105 placed thereon by the robot 104. Following an orientation process being carried out on the substrates placed on the stages 107A, 107B at a first location, the substrates may be aligned and then positioned in multiple orientations at a second location to facilitate laser scribing. In other embodiments, singulated substrates may be positioned in multiple orientations to facilitate laser cutting of a die attached film (DAF) adhered to a membrane. This may take place after substrate etching is carried out in the etching tool 108. More details of the scribing apparatus 106 and its operation are described below with referenced to FIGS. 2A-2D and FIGS. 4-6.

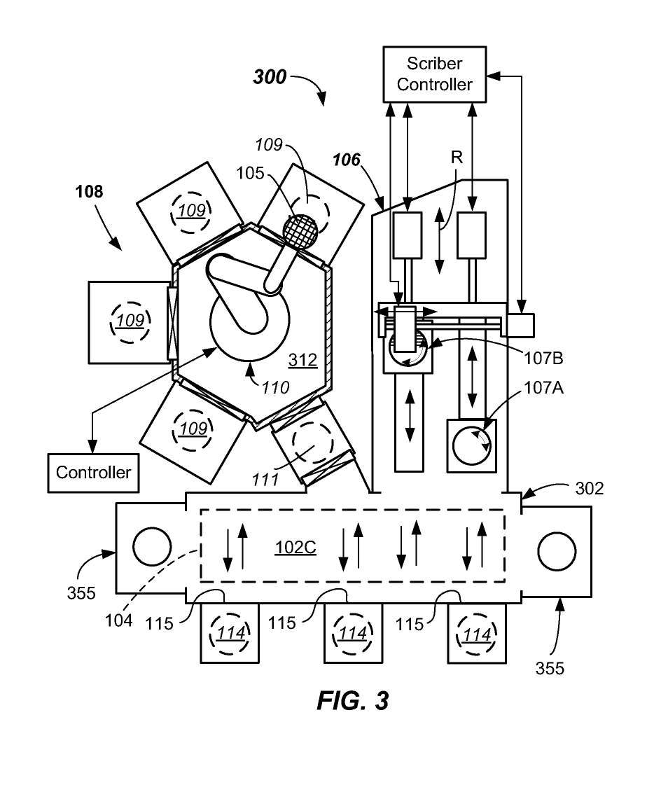

Also coupled to the factory interface 102 is an etching tool 108. The etching tool 108 may include one or more process chambers 109, such as etching chambers that are serviced by a robot 110 (e.g., a SCARA or other multi-link robot) housed in a central transfer chamber 112. An eight faceted transfer chamber is shown. However, any number of facets and transfer chamber configurations may be used, such as three facets, four facets, five facets, six facets, or other numbers of facets. Another suitable embodiment of a five faceted transfer chamber 312 having a SCARA robot is shown in FIG. 3. In some embodiments, a dual robot may be used that simultaneously feeds substrates into two adjacent chambers. Other suitable robot types and transfer chamber orientations may be used.

Again referring to FIG. 1, the transfer chamber 112 includes top, bottom, and side walls, and, in some embodiments, may be maintained in a vacuum, for example. The robot apparatus 110 may have any suitable configuration having multiple arms and is at least partially received in the transfer chamber 112 and is adapted to be operable therein. The robot apparatus 110 may be adapted to pick or place one or more patterned substrates 105 having been scribed by the dual-staged scribing apparatus 106 to or from a destination, such as the process chamber 109. As shown, transfer to the process chamber 109 may be through a slit valve, for example.

Process chambers 109 may be adapted to carry out any number of stages of an etching process on the scribed substrates 105. The etching process is adapted to etch fully or partly through the substrate 105 at the positions of the scribed streets having been previously scribed in the scribing apparatus 106. Other processes may be carried out, as well. For example, one or more of the process chambers 109 may possibly be used for cleaning.

One or more load lock chambers 111 may be adapted to interface with the factory interface 102 and allow transfer of substrates to and from the etching tool 108. In operation, substrates 105 from one or more storage devices 114 situated at locations 115 of the factory interface 102 may be picked up by the robot 104. Storage devices 114 may be substrate carriers (e.g., Front Opening Unified Pods (FOUPs)) situated at load ports of the factory interface 102, for example. In other embodiments, the substrates 105 more simply may be provided and/or stored on shelves coupled to the factory interface 102 at locations 115. The substrates 105 may be adhered to a die attached film (DAF) in some embodiments, which may be arranged and secured in or to a frame.

The robot 104 in the factory interface 102 may pick up a substrate 105 and transport the substrate 105 to the scribing apparatus 106. The substrate 105 may be placed on the first stage 107A, for example. Because the orientation of the streets between the various integrated circuits formed on the substrate 105 are not known, an orientation process is first undergone at the first location. First location may be a location near to the opening 113A of the housing 113. Following the orientation process and laser scribing at a second location, the patterned substrate having scribed street locations formed thereon is removed from the scribing apparatus 106 and then transported by the robot 104 to the one or more load locks 111 for entry into the etching tool 108 where an etching process is carried out.

The robot 104 (shown dotted) may be used to physically transfer substrates 105 between the storage devices 114 (e.g., FOUPs or shelves), the scribing apparatus 106, and the one or more load locks 111 of the etching tool 108, as indicated by the arrows. Transfers of substrates may be carried out in any sequence, order, or direction. In some embodiments, the substrates may be adhered to a membrane that is supported in a frame. The DAF may be located between the substrate and the membrane and may be operational to adhere the substrate to the membrane. The frame may be supported by the robot 104 during transportation.

In more detail, the robot 104 may pick up a patterned substrate 105 from the storage location 114. The substrate 105 may be from a lot of patterned substrates carried or stored by the storage location 114, for example. Robot 104 then may transfer the patterned substrate 105 to the scribing apparatus 106, and insert the patterned substrate 105 into the scribing apparatus 106 through the opening 113 and onto a first stage (e.g., stage 107A) of the two or more stages 107A, 107B. The stages 107A, 107B may be provided in a side-by-side orientation across the scribing apparatus 106, as shown, and may have a load and unload location that is located at approximately a same distance from the opening 113 into the scribing apparatus 106. The loading and unloading location is accessible by the robot 104.

Once placed into the first stage 107A of the scribing apparatus 106 at the loading and unloading location, the scribing apparatus 106 may carry out an orientation process with a vision system 120 carrying out pattern recognition (Not shown in FIG. 1 for clarity, but see FIG. 2A-2C). The orientation process may take place at a first location 117, which may be the loading and unloading location. The orientation process includes determining an orientation of the substrate on the first stage 107A such that the substrate coordinates may be mapped to the coordinates of the stage 107A. This may be followed by an alignment process aligning the substrate 105 such that a first street is aligned with a traversal path of a scribing beam head 119.

As best shown in FIGS. 2A and 2B, during the orientation process, the vision system 120 comprising a camera 122 is mounted above the first stage 107A and centered above the substrate 105. The camera 122 is shown located at the first location 117. The camera 122 may be located at the loading and unloading location when the first location 117 is the loading and unloading location, or optionally, the first stage 107A may move to a first location 117 offset from the loading and unloading location. Once positioned at the first location 117, the vision system 120 captures a digital visual image of the patterned substrate 105. Vision software in an image processor 124A then stores in memory the digital image of the patterned substrate 105. The image processor 124A of the vision system 120 parses that digital image and determines an orientation and position of the various streets between the various integrated circuits formed on the substrate 105 relative to stage coordinates. The parsing may be accomplished by comparing the current digital image to a known digital image (e.g., a golden wafer image) or a digital representation of the patterns used in the manufacturing and compiling a matching score. For example, the differences in intensities of various pixels between the two images may be determined. Then, a suitable image transformation may take place such as image rotations, translations, and scaling. The matching score may be recalculated. A global minimum of the matching score may be obtained by well known techniques. Accordingly, during the orientation process, a location of each street and the rotational orientation of the patterned substrate 105 are precisely determined. The orientation of the patterned substrate 105 may be precisely determined relative to known orientating indicia or marks provided at suitable locations on the first stage 107A.

Accordingly, the image software determines the exact locations of the streets on the patterned substrate 105 where scribing will take place. Moreover, the image software of the image processor 124A determines based upon the image and the indicia, a precise amount of rotation to impart in order to rotationally align the substrate 105 so that the streets will be aligned in a parallel alignment to a transversal path of the scribing beam head 119 and scribing beam 116.

An alignment process may be carried out by rotation of a platen of the first stage 107A, upon which the substrate 105 is placed, by stage motor 107C. Stage motor 107C may be a stepper motor or the like. Additionally, Stage motor 107C may include suitable feedback encoders. Other suitable precision motors may be used. Stage motor 107C may receive drive instructions from a scriber controller 124B that carries out various instructions (e.g., stage motion and laser firing) of the scriber apparatus 106. Image processor 124A and scriber controller 124B may communicate. Such image processing and control instructions may be carried out by a common computer system including memory and a suitable processor in some embodiments. The control system may include various drive circuits and filtering and conditioning components (not shown) that are adapted to drive the stage motors 107C, 107D and operate the camera 122.

Once the orientation process is completed, the patterned substrate 105 may be aligned by carrying out the alignment process via rotating the stage 107A by the predetermined amount to the proper rotational alignment so that scribing may take place along a first street. Additionally, the alignment process may include translating the patterned substrate 105 on the first stage 107A in the R direction to a second location 125 below a path of the beam delivery head 119. The second location 125 may be a location in the R direction where the first street to be scribed on the substrate 105 is positioned in proper R alignment with an R position of the scribing beam 116. The translation of the first stage 107A in the R direction to the second location 125 may be accomplished by an R actuator 107E coupled to a slide 107F of the first stage 107A. R actuator 107E may be a suitable precision linear actuator and may also include a suitable feedback encoder. Another R actuator, like R actuator 107E may be provided on the second stage 107B. Actuation of the R actuator 107E via control signals from the scriber controller 124B causes the slide 107F to slide on the support 113B and move to the second location 125 as shown in FIG. 2C. The steps of rotation in the Theta direction and translation in the R direction may be reversed or carried out simultaneously in some embodiments. The operation and structure of the second stage 107B may be substantially identical to the first stage 107A.

Now referring to FIGS. 2A-2C, the scribing beam 116 may be generated by two or more lasers 118A, 118B that are directed at the beam delivery head 119. The lasers 118A, 118B generate laser beams 119A, 119B which may be further shaped, collimated, expanded, and/or diverted by various optical components. In the depicted embodiment, the laser beams 119A, 119B may be passed through beam shapers 126A, 126B, which may shape the laser beams 119A, 119B to have a more uniform light intensity profile across their width. Each beam shaper 126 may be a model F-pi shaper NA Series available from n shaper of Berlin, Germany, for example. The laser beams 119A, 119B may be sent through beam expanders 128A, 128B, which may function to further expand the laser beams 119A, 119B and/or make them more cylindrical. Each beam expanders 128A, 128B, may be a model HEBX-4.0-2X-532 available from CVI-Melles Groit of Albuquerque, NM, for example. Each of the lasers 118A, 118B may be a model Hyper Rapid 50 available from Lumera Laser of Kaiserslauten, Germany, for example having an average output of less than about 50 W, for example.

The laser beams 119A, 119B may be diverted and projected by free space optics 129 including one or more mirrors 129A, 129B, 129C and delivered to the beam delivery head 119. Projected and diverted laser beams 119A, 119B are combined by the action of the free space optics 129 and optics in the beam delivery head 119 such that the two laser beams 109A, 109B are provided in a physically close proximity to one another. Generally the laser beams 119A, 119B may be located within about 1-10 mm of each other in the beam delivery head 119. The combined laser beams 119A, 119B may be emitted from the beam delivery head 119 as the scribing beam 116.

Beam delivery head 119 emitting the scribing beam 116 is traversed along a traversal path on a gantry 121. Gantry 121 may be coupled to the housing 106H and made of any suitable rigid construction, such as a cross beam 123A and worm drive 123B shown. Cross beam 123A may include precision slides or other precision geometric features on which the beam delivery head 119 may slide. Drive mechanism 123B, such as a worm drive 123B may be driven by gantry motor 123C via a drive signal from the scriber controller 124B and rotation thereof moves the beam delivery head 119 back and forth along a traversal path with high precision as commanded. Optionally, a linear drive motor may be used.

FIG. 2D illustrates an embodiment of a beam delivery head 119 in more detail. The beam delivery head 119 may include a housing 230, internal free space optics 232 such as mirrors 232A, 232B, a multi-faceted rotary reflector 234, and an F-theta lens 236. In operation, the combined beams 119A, 119B are received into a port 238 of the beam delivery head 119 and are reflected off from the mirrors 232A, 232B and onto the multi-faceted rotary reflector 234. The multi-faceted rotary reflector 234 may be rotated at a rotational speed of between about 100 rev/s and about 10,000 rev/s. Rotation may be started via a signal from the scriber controller 124B. Reflection off from the various facets 240 (a few labeled) of the multi-faceted rotary reflector 234 during its rotation causes the laser beams 119A, 119B to be reflected from the facets 240 and projected into the F-theta lens 236. The F-theta lens 236 may have an operational wavelength between about 400 nm and about 1000 nm and a focal length of between about 10 mm and about 100 mm, and may have a scan field of between about 10 mm and about 50 mm, for example. Other values may be used. The construction of the beam delivery head 119 causes the scribing beam 116 to be rastered at a rapid rate back and forth across the field of the F-theta lens 236. Thus, as the beam deliver head 119 is traversed along its traversal path on the gantry cross beam 123, the scribing beam 116 will also raster along that path. In other words, the rastering of the scribing beam 116 is superimposed upon the traversal of the scribing beam 116 caused by the back and forth motion of the beam delivery head 119.

As shown in FIG. 2C, beam delivery head 119 emitting scribing beam 116 traverses across the substrate 105 on the first stage 107A along the transverse path. Upon full or near full traversal across the substrate 105, first stage 107A may be incremented by one street in the R direction by actuator 107E and the scribing beam 116 may be traversed back across the substrate 105 on the first stage 107B along the transverse path by the movement of the beam delivery head 119. Traversal rates may between 100 mm/s and 2000 mm/s, for example. Other rates may be used. Thus, scribing beam 116 traverses back and forth while it may be incremented a street at a time as the scribing beam 116 scribes through (e.g., ablates) the protective film that was previously applied over the substrates 105. Upon completion of scribing in one direction, the first stage 107A may be rotated 90 degrees by the stage motor 107C and the scribing process may be started again along the streets between the respective integrated circuits in another direction. Upon completion of the full scribing process on all the streets on the substrate 105, the first stage 107A may be moved in the R direction back to the first location 117 adjacent to the opening 113. The scribed substrate 105 may then be picked up off from the first stage 107A and transported by the robot 104 to the etching tool 108 where an etching process may be carried out to singulate the substrate into dice.

Likewise, the second stage 107B goes through the same steps as described above for the first stage 107A. However, the two stages 107A, 107B are processing substrates 105 out of sequence with one another. In particular, when the first stage 107A is undergoing an orientation at the first location 117, the second stage 107B is positioned at the second location 125 and is undergoing a laser scribing process. When second stage 107B is undergoing an orientation process at the first location 117, the first stage 107A is positioned at the second location 125 and is undergoing a laser scribing process. In this manner, throughput is substantially increased. Throughput of greater than 35 wafers per hour (wph), greater than 40 wph, or even greater than 45 wph, or even about 50 wph or more may be achieved. Additionally, combining the two laser beams 119A, 119B generates a high intensity scribing beam 116, while using relatively low power lasers 118A, 118B. In particular, a DAF scribing step may be carried out according to another aspect.

Upon transfer from the scribing apparatus 106 to the etching tool 108, insertion may be in an out through both load locks 111 shown, or in through one load lock 111 and out through the other load lock 111. Once in the transfer chamber 112, substrates may be inserted into one or more process chambers 109 to carry out etching, cleaning, or other processes thereon.

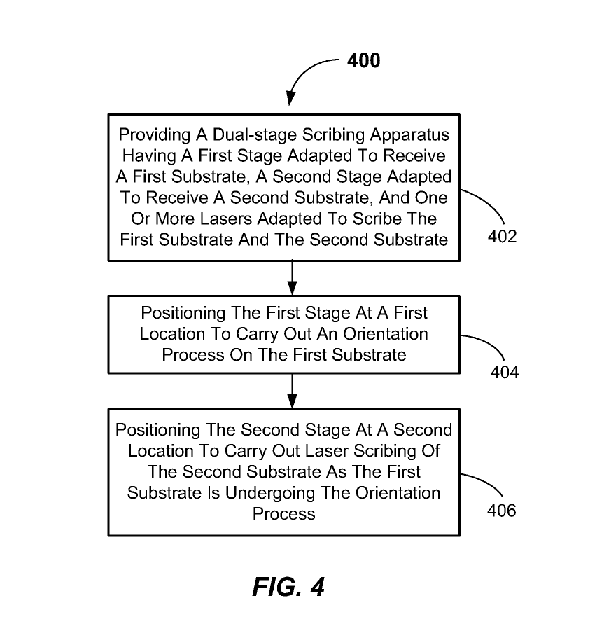

Now referring to FIG. 4, a method 400 of processing a substrate within an electronic device processing system (e.g., 100) is disclosed. The method 400 includes, in block 402, providing a dual-stage scribing apparatus (e.g., scribing apparatus 106) having a first stage (e.g., first stage 107A) adapted to receive a first substrate, a second stage (e.g., second stage 107B) adapted to receive a second substrate, and one or more lasers (e.g., lasers 118A, 118B) adapted to scribe the first substrate and the second substrate. The method 400 includes, in 404, positioning the first stage at a first location (e.g., first location 117) to carry out an orientation process on the first substrate, and in 406 positioning the second stage at a second location (e.g., second location 125) to carry out laser scribing of the second substrate as the first substrate is undergoing the orientation process. The orientation process, as described above, involves recognizing a pattern of integrated circuits on the substrate via an imaging system 120 so that the substrates coordinates can be mapped to the stage coordinates, i.e., to precisely locate the streets on the substrate.

In another aspect, following the laser scribing of the second substrate, the substrate may be transferred to the etching tool 108. An etching process may be carried out in the etching tool 108 to singulate the substrate. The location in the scriber apparatus 106 vacated by the second substrate may be reloaded with another substrate to be scribed. Likewise, as soon as the orientation process, alignment process, and scribing processes take place on the first substrate, it too may be transferred to the etching tool 108 for etching and singulation. The first substrate may also be replaced with another substrate.

In another broad method aspect of the invention, after the etching process at the etching tool 108 has taken place to form a singulated substrate, a method 500 of processing the singulated substrate may take place. As described above and as shown in FIG. 6, certain substrates 605 may be adhered to a membrane 645 having a die attached film formed thereon, which may be a polymer adhesive material having a thickness of between about 50 μm and about 100 μm. The membrane 645 may be secured by or on a frame 648, which may have a hoop shape. Other shapes may be used as well. After the etching process is completed thereby forming a singulated substrate 605 having a plurality of dice 650, the DAF may be laser cut so that when the dice 650 may be more easily separated from the membrane 645, and wherein the DAF is retained on the bottom of the dice 650. In another aspect, as should be apparent from the foregoing, the dual-stage scribing apparatus 106 may allow a DAF on a singlulated substrate returning from the etching tool 108 to be oriented, aligned, and laser cut on one stage (e.g., a first stage 107A), while a scribing process may be talking place on a patterned substrate on the second stage (e.g., stage 107B), or vice versa. In some embodiments, DAF cutting may take place on one stage (e.g., a first stage 107A), while a singlulated substrate returning from the etching tool 108 may be oriented and aligned, on the other stage (e.g., a second stage 107MB), or vice versa

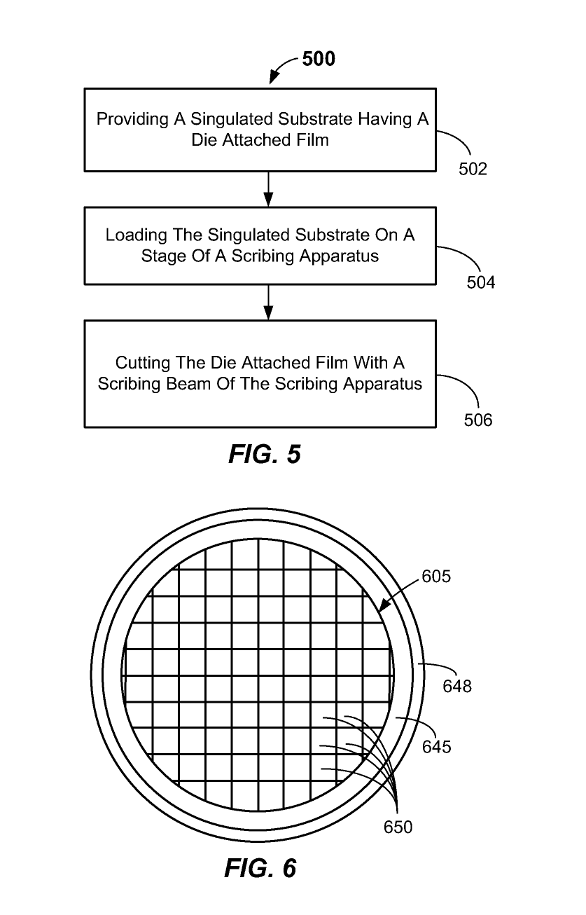

The method 500 of processing the singulated substrate 605, in this embodiment, is a DAF cutting method, as shown in FIG. 5. The method 500 includes, in block 502, providing a singulated substrate having a DAF (e.g., DAF is provided on membrane 645 in FIG. 6); in 504, loading the singulated substrate (e.g., singulated substrate 605) on a stage (e.g., first stage 107A) of a scribing apparatus (e.g., scribing apparatus 106), and in block 506, cutting the DAF with a scribing beam (e.g., scribing beam 116) of the scribing apparatus (e.g., scribing apparatus 106). In one or more embodiments, the scribing apparatus may be like scribing apparatus 106 having a first laser 118A and a second laser 118B whose laser beams are combined to form the scribing beam 116.

The scribing apparatus may have only a single stage, or may be a dual-stage scribing apparatus 106 comprising two or more stages 1087A, 107B, as are described with reference to FIGS. 2A-2D herein. In one embodiment, the DAF on membrane 645 is cut on a dual stage scriber 106 having two or more lasers (e.g., lasers 118A, 118B). As part of the DAF cutting method 500, the orientation of the singulated substrate 605 may be determined prior to the cutting in block 506. The orientation may be determined by the vision system 120, as previously described. In particular, die may move in the etching process, making orientation desirable. Following the orientation being determined, the singulated substrate 605 may be aligned with the traversal path of the scribing beam head 119 and then cutting may commence in the same manner as described for the scribing process. In short, the DAF on the membrane 645 is cut along the streets to help retain the DAF on the bottom each of the dice 650 when they are subsequently separated from the membrane 645.

Referring again to FIG. 3, another embodiment of an electronic device processing system 300 is shown. The electronic device processing system 300 includes a one or more optional coating apparatus 355 coupled to the factory interface 302. The coating apparatus 355 are operational to apply a protective coating on the substrates (e.g., on the first substrate and second substrates 105) that are being sent to the scribing apparatus 106 for scribing. The coating apparatus 355 includes a suitable metering system and spray or spin coater adapted to spray dispense a thin layer of the protective coating onto the substrate 105 placed thereat by robot 104. Coating may be a polymer coating having a thickness of between about 10 μm and 200 μm, for example. Other coating types and thicknesses may be used. Coating apparatus 355 may include a door that may be closed during the coating process, and may include suitable ventilation. After applying the coating, the coating apparatus 355 may heat the coating, or the coating may be cured or otherwise hardened. The curing may be by heating the coating, and may take place in a separate chamber or at a separate location. For example, the substrate may rest on a conductively heated platen. In other embodiments, the coating may be a UV curable coating and may be cured by application of a UV light. Other suitable means for curing or hardening the coating may be used. Following coating, the substrate may be delivered to the scribing apparatus 106 for scribing.

The foregoing description discloses only example embodiments of the invention. Modifications of the above-disclosed systems, apparatus, and methods which fall within the scope of the invention will be readily apparent to those of ordinary skill in the art. Accordingly, while the present invention has been disclosed in connection with example embodiments thereof, it should be understood that other embodiments may fall within the scope of the invention, as defined by the following claims.

What is claimed is:

1. A scribing apparatus, comprising:
a first stage adapted to receive a first substrate,
a second stage adapted to receive a second substrate, and
one or more lasers adapted to emit a laser beam towards the first stage and the second stage and adapted to scribe the substrates.

2. The scribing apparatus of claim 1, wherein the first stage and the second state are arranged in a side-by-side orientation.

3. The scribing apparatus of claim 1, wherein the first stage comprises a rotary stage.

4. The scribing apparatus of claim 1, wherein the first and second stages comprise rotary stages.

5. The scribing apparatus of claim 1, wherein the first and second stages comprise side-by-side R-Theta stages configured to rotate the first and second substrates in Theta and translate the first and second substrates in R.

6. The scribing apparatus of claim 1, wherein the one or more lasers comprise two lasers whose laser beams are combined to form a scribing laser beam.

7. The scribing apparatus of claim 1, wherein the two lasers utilize free space optics.

8. The scribing apparatus of claim 1, wherein the scribing apparatus is configured to have a first operational configuration where the first substrate on the first stage is located to undergo an orientation process while the second substrate on the second stage is located to undergo a laser scribing process.

9. The scribing apparatus of claim 1, wherein the scribing apparatus is configured to have a second operational configuration where the first substrate on the first stage is located to undergo a laser scribing process while the second substrate on the second stage is located to undergo an orientation process.

10. The scribing apparatus of claim 1, comprising a beam delivery head adapted to move between the first stage and the second stage to carry out laser scribing of the first substrate and the second substrate.

11. The scribing apparatus of claim 1, comprising a beam delivery head adapted to move on a gantry between the first stage and the second stage to carry out laser scribing.

12. The scribing apparatus of claim 1, wherein the first and second stages each comprise an R translation drive adapted to move each of the first stage and the second stage from a first location adapted to carry out orientation process to a second location adapted to carry out a laser scribing process.

13. An electronic device processing system, comprising:
a factory interface;
an etching tool coupled to the factory interface; and
a dual-stage scribing apparatus coupled to the factory interface.

14. The electronic device processing system of claim 13, wherein the dual-stage scribing apparatus comprises:
a first stage adapted to receive a first substrate,
a second stage adapted to receive a second substrate, and
one or more lasers adapted to emit a laser beam towards the first stage and the second stage and adapted to scribe the substrates.

15. The electronic device processing system of claim 14, wherein the first stage and the second state are arranged in a side-by-side orientation and each of the first and second stages are moveable in both of an R and a Theta direction.

16. The electronic device processing system of claim 13, wherein the dual-stage scriber comprises a beam delivery head adapted to move between the first stage and the second stage to carry out laser scribing of substrates located on the first and second stages.

17. The electronic device processing system of claim 13, wherein the dual-stage scribing apparatus comprises two lasers.

18. A method of processing a substrate within an electronic device processing system, comprising:
providing a dual-stage scribing apparatus having a first stage adapted to receive a first substrate, a second stage adapted to receive a second substrate, and one or more lasers adapted to scribe the first substrate and the second substrate;
positioning the first stage at a first location to carry out an orientation process on the first substrate; and
positioning the second stage at a second location to carry out laser scribing of the second substrate as the first substrate is undergoing the orientation process.

19. The method of processing a substrate of claim 18, comprising:
after scribing the second substrate, transferring the second substrate through a factory interface to an etching tool.

20. The method of processing a substrate of claim 19, comprising:
returning the second substrate to the dual-stage scribing apparatus after carrying out an etching process in the etching tool.

21. The method of processing a substrate of claim 18, comprising:
cutting a die attached film with a scribing beam of the dual-stage scribing apparatus.

22. The method of processing a substrate of claim 18, comprising applying a coating on the first substrate and second substrate within a coating apparatus coupled to the factory interface.

23. A method of processing a singulated substrate, comprising:
providing a singulated substrate having a die attached film;
loading the singulated substrate on a stage of a scribing apparatus; and
cutting the die attached film with a scribing beam of the scribing apparatus.

24. The method of processing a singulated substrate of claim 23, wherein the cutting comprises:
combining two laser beams at a beam delivery head to form the scribing beam.

25. A scribing apparatus, comprising:
a stage adapted to receive a substrate;
a beam delivery head adapted to produce a scribing beam;
a first laser adapted to emit a laser beam towards the beam delivery head; and
a second laser adapted to emit a laser beam towards the beam delivery head
wherein the first beam and second beam are combined within the beam delivery head and produce the scribing beam.
